(19) United States
(12) Patent Application Publication
(10) Pub. No.: US 2015/0316711 A1
(43) Pub. Date: Nov. 5, 2015

(54) SMALL FOOTPRINT LIGHT PIPE PCB MOUNTING ADAPTOR

(71) Applicant: DAVID C. NORTH, SANTA CLARA, CA (US)

(72) Inventor: DAVID C. NORTH, SANTA CLARA, CA (US)

(73) Assignee: ALCATEL-LUCENT USA INC., MURRAY HILL, NJ (US)

(21) Appl. No.: 14/266,285

(22) Filed: Apr. 30, 2014

(51) Int. Cl. F21V 8/00; H05K 1/02

(52) U.S. Cl. CPC G02B 6/0096; G02B 6/0005; H05K 1/0274; H05K 2201/10121

(57) ABSTRACT

An apparatus and system providing a relatively low-profile, low-angle, small-footprint adapter for mounting a flexible light pipe to a PCB such that light may be readily transmitted from a PCB surface mounted LED through the light pipe.

### TECHNICAL FIELD

The invention relates generally to light pipes and, more specifically but not exclusively, to a low-profile adapter for mounting a light pipe to a printed circuit board including a surface mounted light emitting diode.

### BACKGROUND

A light pipe is an optical fiber, transparent plastic rod or similar optically transmissive medium for transmitting light from, illustratively, a light emitting diode (LED) or other light source to wherever the light is needed. Light pipes are commercially available and relatively inexpensive. To couple light from a printed circuit board (PCB) mounted light source, such as a PCB mounted LED, current practice is to use a vertically oriented adapter to secure the light pipe to the PCB mounted light source. The vertically oriented adapter provides mechanical and optical cooperation between the PCB mounted light source and the light pipe by mechanically fixing the light pipe in a perpendicular orientation with respect to the plane of the PCB upon which the LED is mounted.

A flexible light pipe may comprise a plastic fiber covered in a protective vinyl sheath. The flexible light pipe has a minimum bend radius to prevent fiber breakage. When the vertical adapter is used the resulting pipe bend may be greater than the height of nearby PCB component and can be easily snagged. In addition the vertical adapter has a relatively large footprint, taking up valuable board space. Thus, where the light is needed in a direction not perpendicular to the PCB, the minimum bend radius associated with even a flexible light pipe may require too much “headroom” with respect to the particular application.

### SUMMARY

Various deficiencies of the prior art are addressed by the present invention of method, apparatus and system providing a relatively low-profile, low-angle, small-footprint adapter for mounting a commercially available flexible light pipe to a PCB such that light may be readily transmitted from a PCB surface mounted LED (e.g., a side-firing (right-angle) surface-mount LED) to a user interface panel or other light destination.

An apparatus for receiving the light pipe at a printed circuit board (PCB) according to one embodiments comprises a body having a front portion, a rear portion, an inner portion and a base portion, the inner portion configured to form a cavity through the front portion and configured to receive a light pipe inserted therein, the rear portion configured to control a depth of inner portion insertion of the light pipe and allow optical communication between the light pipe and a PCB mounted component, the base portion configured to rest upon a surface of the PCB and position the body to receive the light pipe at a predefined acute angle with respect to the surface of the PCB; and a mounting mechanism adapted to secure the body to the PCB.

### BRIEF DESCRIPTION OF THE DRAWING

The teachings of the present invention can be readily understood by considering the following detailed description in conjunction with the accompanying drawings, in which:

FIG. 1 depicts a side view of a system utilizing a low-profile flexible light pipe adapter according to various embodiments;

FIG. 2 depicts an isometric view of the system of FIG. 1; and

FIG. 3 depicts an isometric view of light pipe adapter suitable for use in the system 100 discussed above with respect to FIGS. 1-2.

To facilitate understanding, identical reference numerals have been used, where possible, to designate identical elements that are common to the figures.

### DETAILED DESCRIPTION

The invention will be primarily described within the context of a light pipe adapter providing mechanical and optical cooperation between a light pipe, illustratively a flexible light pipe, and a PCB mounted LED. However, those skilled in the art and informed by the teachings herein will realize that the invention is also applicable to other systems for flexibly mounting light pipes or similar structures to a PCB or other service.

Various embodiments provide a relatively low-profile, small-footprint adapter for mounting a commercially available flexible light pipe to a PCB such that light may be readily transmitted from a PCB surface mounted LED to a user interface panel or other light destination.

Various embodiments provide a low-profile, angled-entry flexible light pipe adapter for use with a side-firing (right-angle) surface-mount LED on a printed circuit board or other surface.

Generally speaking, a low-profile flexible light pipe adapter as provided herein comprises an apparatus to orient and restrain a flexible light pipe with its exposed optic fiber in line with (i.e., optically cooperating with) light emitted from a right-angle LED.

The adapter may in various embodiments be snap-mounted to a hole in a PCB. The adapter may include a peg adapted to be received by the PCB to thereby prevent rotation of the adapter, thereby assuring an appropriate relative orientation of pipe to LED. A snap-fit structure may also be provided to help a user grip the light pipe firmly when inserted the light pipe or portions thereof into the light pipe adapter. The adapter generally allows the light pipe to dip into the hole to thereby urge a centerline of an the optic fiber to align with a primary face of the PCB mounted LED.

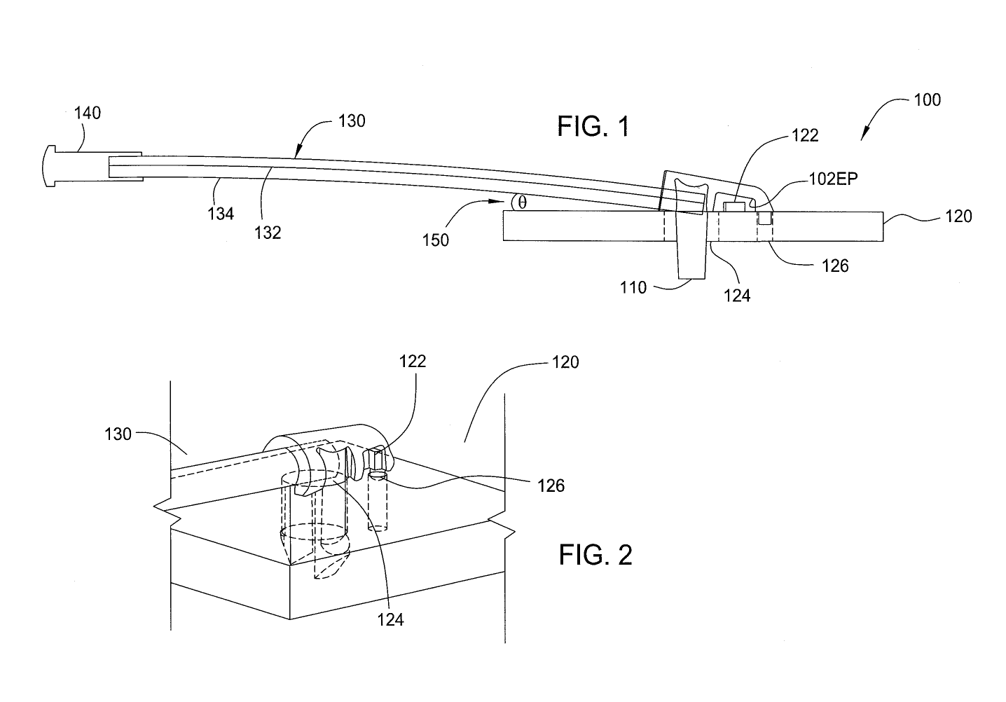

FIG. 1 depicts a side view of a system utilizing a low-profile flexible light pipe adapter according to various embodiments. Specifically, FIG. 1 depicts an “edge on” view of a printed circuit board (PCB) having mounted thereon a surface mounted LED and a light pipe adapter according to one embodiment. FIG. 2 depicts an isometric view of the system of FIG. 1. The two figures will be discussed together.

The system 100 of FIGS. 1 and 2 comprises a light pipe adapter 110 mounted upon a printed circuit board (PCB) 120 proximate a PCB surface-mounted LED 122. The light pipe adapter 110 receives a proximate end of a light pipe 130 at an acute angle with respect to the PCB 120; the light pipe adapter 110 mechanically securing the proximate end of light pipe 130 and placing the light pipe 130 into optical alignment with the LED 122.

The light pipe 130 comprises a standard light pipe including an optical fiber or other transparent medium 132 enclosed within a plastic sheath or other protective medium 134. The proximate end of the light pipe 130 is adapted to receive light from, illustratively, an LED or other light source. The received light is propagated through the optical fiber or other transparent medium 132 toward the distal end of the light pipe 130. As shown, the distal end of the light pipe 130 is communicatively coupled to a display element 140, such as a diffuser or other optical device. The display element 140 may comprise, illustratively, an indicator element on a user interface or equipment panel.

The PCB 120 comprises a standard PCB having mounted thereon an LED 122 or other light emitting device. The PCB 120 is depicted as including two holes on either side of the LED 122; namely, an adapter mounting hole 124 and an adapter anti-rotation hole 126. The adapter mounting hole 124 is sized to accept mounting prongs 104 associated with the adapter 110, the mounting prongs 104 operative to secure the adapter 110 to the PCB 120. The adapter anti-rotation hole 126 is sized to accept an anti-rotation tab 106, the anti-rotation tab 106 operative to resist rotation of the adapter 110.

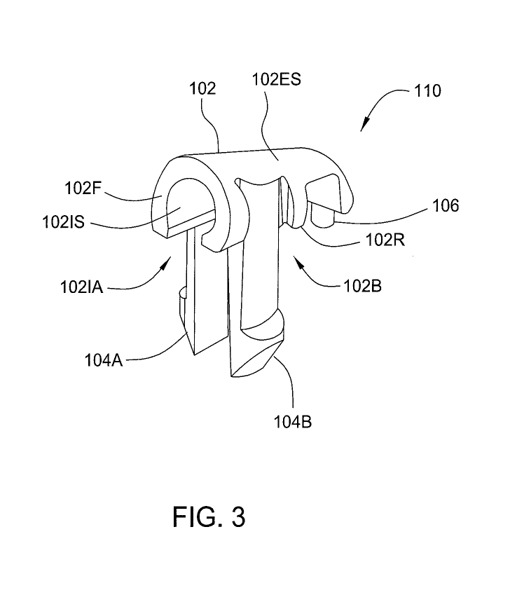

FIG. 3 depicts an isometric view of light pipe adapter 110 suitable for use in the system 100 discussed above with respect to FIGS. 1-2.

The light pipe adapter 110 comprises a body portion 102 depicted as substantially cylindrical in nature having an exterior surface 102ES and an interior surface 102IS, the interior surface 102IS defining thereby an arcuit cavity for receiving the light pipe 130 at a front or face portion of the light pipe adapter 110. The body portion 102 further includes an annular ring 102R or functionally equivalent structure (e.g., a partial annular ring, one or more partial annular rings, tabs, dimples, bumps and the like) protruding into the cavity from the interior surface 102IS central wall and adapted to impede further insertion of the light pipe 130 within the light pipe adapter 110. The body portion 102 further includes a base 102B or functionally equivalent structure configured to contact or rest upon the top surface of the PCB 120 such that the light pipe adapter 110 is appropriately aligned and mechanically secure.

The light pipe adapter 110 further comprises a PCB mounting mechanism. FIG. 2 depicts a mounting mechanism protruding from the body portion 102 and configured to be received by the PCB. Specifically, the depicted mounting mechanism comprises two mounting clips 104A and 104B, the mounting clips 104 adapted for insertion into the adapter mounting hole 124 of the PCB 120. The mounting clips 104 are depicted as having spring preload or bias such that upon insertion through the mounting hole 124 of the PCB 120 (after first being compressed inward toward each other to fit in the hole), the mounting clips are urged outward such that the PCB retaining structure at the end of each mounting clip 104 cooperates with the inner edge of the mounting hole 124 and underside of the PCB 120 to mechanically secure the light pipe adapter 110 to the PCB 120. That is, the mounting clips protrude through the PCB 120 to mechanically secure the light pipe adapter 110 such that the base portion 102B of the body portion 102 is resting upon the top surface of the PCB 120.

Mounting mechanism depicted herein comprises a “clip on” type of mounting mechanism wherein one or more clips or legs protruding from the lower or base portion 102B of the body 102 are configured for insertion through one or more openings or holes through the PCB 120 to secure the light pipe adapter 110 thereto. The various other embodiments, the light pipe adapter 110 may comprise a two-piece adapter wherein a first or bottom piece is mounted to the PCB 120 via adhesive, soldering or other technique, while a mating second or top piece mechanically cooperates with the bottom piece to be secured thereby to the PCB 120.

The body portion 102 of the light pipe adapter 110 optionally comprises an extended portion 102EP which is configured to extend over the mounted LED 122 (or other components) and contact the surface of the PCB 120 to provide additional mechanical support. FIG. 2 depicts an extended portion 102EP of a particular size and shape extending over the LED 122 and contacting the PCB 120. The size and shape may be adapted to provide additional strength/rigidity as needed. Further, the length of the extended portion 102EP may be extended to contact the PCB 120 at a greater distance than depicted, to extend over more PCB components prior to contacting the PCB 120 and so on.

The light pipe adapter 110 optionally comprises an anti-rotation tab 106 protruding from a lower rear portion of the body portion 102, the anti-rotation tab 106 configured for insertion into the anti-rotation hole 126 of the PCB 120. FIG. 2 depicts the anti-rotation tab 106 is protruding from a lower portion of the extended portion 102 EP of the body portion 102 of the light pipe adapter 110. In various embodiments, multiple anti-rotation tabs 106 may be used where each anti-rotation tab 106 protrudes through a respective anti-rotation hole 126 or a respective portion of a common anti-rotation slot (not shown) within the PCB 120.

The light pipe adapter 110, when mounted to the PCB 120, is adapted to receive a light pipe via the front facing cavity defined within the body portion 102 of the light pipe adapter 110. In various embodiments, the cavity defined within the body portion 102 is such that the light pipe is received at a slight or acute angle 150 with respect to the plane of the PCB 120.

In various embodiments, this angle 150 is selected to be approximately 10°. The 10° selection enables a low attack angle for the light pipe to enter the adapter to provide thereby closer proximity of the end of the light pipe and the PCB mounted LED. Various changes to this angle may be made in response to manufacturing considerations, cable/component layout considerations, and spatial light distribution specifications of the LEDs to which the light pipe will be communicating (depends on LED lens shape and other factors), tolerable bend radius of the light pipe to be employed, the size and layout of the PCB and/or equipment within which the PCB is to be mounted, as well as other layout and/or routing considerations associated with the application. In one application with one particular LED, a 10° attack angle was found to yield approximately 98% of the LED output, whereas a 40° attack angle was found to yield approximately 80% of output. Useful attack angles have been found from a range of almost horizontal (i.e., 0°) to above 50° depending upon the LED characteristics.

Generally speaking, the attack angle and other geometry associated with the adapter is configured such that the light pipe 130 is received in a manner providing mechanical and optical cooperation between the light transmissive portion of the light pipe 130 and the LED 122. In various embodiments, the angle is such that the light pipe is placed on or almost upon the surface of the PCB such that a right angle LED may propagate its optical energy into the light pipe in a maximally efficient manner.

Various embodiments may be adapted to change the attack angle, such as to provide sufficient flexibility to allow the attack angle to change between, illustratively, 5° and 40°.

The system 100 provides simplified assembly in that the PCB 120 having mounted thereon the LED 122 receives the light pipe adapter 110 via a snap on connection provided by the mounting clips 104 and, optionally, anti-rotation tab 106. After the simple mechanical connection of the light pipe adapter 110 and the PCB 120, a light pipe 130 may be mechanically inserted into the front facing cavity defined within the body portion 102 of the light pipe adapter 110. The depth of insertion of the light pipe 130 into the light pipe adapter 110 is controlled by the stop ring 102R, interior retaining tabs or other structure formed within the body portion 102 defining the cavity.

In various embodiments, the cavity defined within the body portion 102 is shaped differently. For example, the cavity formed within the body portion 102 is adapted to receive a light pipe 130 having a substantially cylindrical shape. However, in other embodiments, the cavity formed within the body portion 102 is adapted to receive light pipe having different shapes, such as extruded rectilinear shapes, triangular shapes and the like. Various embodiments contemplate a conical shaped cavity wherein an inserted light pipe is secured therein via a compression fit. Advantageously, such a conical shaped cavity is well suited to injection molding manufacturing techniques. Various embodiments contemplate a body having an extended front portion to provide therein a longer and/or wider cavity than otherwise described herein.

In various embodiments, the mechanism for impeding further insertion of the light pipe 130 within the light pipe 110 may comprise a structure different than the interior annular ring 102R as described herein. For example, any structure formed at the inner surface 102IS the body portion 102 operative to impede insertion of the light pipe 130 beyond a desired position may be employed for this purpose. Such structure may comprise one or more tabs, annular ring portions and so on.

In various embodiments, the mechanism for securing the light pipe 110 to the PCB 120 may comprise a structure different than the mounting clips 104 described herein. For example, any structure adapted to secure the light pipe 110 to the PCB 120 may be used. Different clip styles may be used. Clip styles having different securing mechanisms and/or securing tips may be used. A screw or other mechanical fastener may also be used for the primary mechanical support function and/or the anti-rotation function.

The various embodiments discussed herein may be fabricated in a standard manner using various plastic, metal or other materials as a be known to those skilled in the art.

The various embodiments provide thereby a low-profile, angled-entry flexible light pipe adapter for use with, illustratively, a side-firing (right-angle) surface-mount LED on a printed circuit board. The low-profile flexible light pipe adapter orients and restrains a flexible light guide and its exposed optic medium within spatial distribution angle appropriate for a right-angle LED. The adapter may be snap-mounted to a hole in a PC board and may further have a peg to prevent rotation, assuring the relative orientation of light pipe to LED. The snap-fit feature also helps to firmly grip the light pipe when being received. The adapter allows the light pipe to be received in a manner bringing the centerline of the optic fiber within the appropriate spatial distribution angle of a primary face of the LED.

Although various embodiments which incorporate the teachings of the present invention have been shown and described in detail herein, those skilled in the art can readily devise many other varied embodiments that still incorporate these teachings. Thus, while the foregoing is directed to various embodiments of the present invention, other and further embodiments of the invention may be devised without departing from the basic scope thereof. As such, the appropriate scope of the invention is to be determined according to the claims.

What is claimed is:

1. Apparatus for receiving the light pipe at a printed circuit board (PCB), comprising:
a body having a front portion, a rear portion, an inner portion and a base portion;
the inner portion configured to form a cavity through the front portion and configured to receive a light pipe inserted therein;
the rear portion configured to control a depth of inner portion insertion of the light pipe and allow optical communication between the light pipe and a PCB mounted component;
the base portion configured to rest upon a surface of the PCB and position the body to receive the light pipe at a predefined acute angle with respect to the surface of the PCB; and
a mounting mechanism adapted to secure the body to the PCB.

2. The apparatus of claim 1, wherein the inner portion is configured to form a substantially cylindrical cavity.

3. The apparatus of claim 1, wherein the rear portion comprises an annular ring formed upon the surface of inner portion and configured to impede forward progress of a light pipe inserted within the inner portion.

4. The apparatus of claim 1, wherein the rear portion comprises at least one of a partial annular ring, a tab, a dimple and a bump; formed upon the surface of the inner portion and configured to impede forward progress of a light pipe inserted within the inner portion.

5. The apparatus of claim 1, wherein the mounting mechanism comprises a plurality of legs extending from the body and configured to be received by a PCB opening for securing the apparatus thereby.

6. The apparatus of claim 5, wherein each leg has a tip configured to cooperate with the back portion of the PCB for securing the apparatus thereby.

7. The apparatus of claim 1, wherein the body further comprises an extended portion configured to extend over a PCB mounted component and contact the surface of the PCB.

8. The apparatus of claim 7, wherein the extended portion further includes at least one anti-rotation tab configured for insertion into a corresponding PCB opening to thereby further secure the apparatus.

9. The apparatus of claim 1, wherein the predefined acute angle comprises an angle selected between 5° and 40°.

10. The apparatus of claim 1, wherein the predefined acute angle comprises an angle of approximately 10°.
